(19) United States
(12) Patent Application Publication
(10) Pub. No.: US 2009/0146295 A1
(43) Pub. Date: Jun. 11, 2009

(54) Ceramic substrate having thermal via

(76) Inventors: Hidefumi Narita, Kanagawa-ken (JP); Akira Inaba, Ibaraki-ken (JP)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 12/001,267

(22) Filed: Dec. 11, 2007

(51) Int. Cl. H01L 23/36; H01L 23/42; H01L 21/02

(52) U.S. Cl. 257/720; 438/122; 438/637; 257/700; 257/E23.101; 257/E21.002

(57) ABSTRACT

The present invention relates to a ceramic substrate having a thermal via passing through the substrate for purposes of radiating heat to the outside, wherein the ceramic substrate has a reinforcing structure that divides the opening of the thermal via into two or more parts, and the height of the reinforcing structure is less than the height of the thermal via.

### BACKGROUND OF THE INVENTION

1. Field of the Invention:

The present invention relates to the structure of a thermal via provided in a ceramic substrate.

2. Technical Background:

As more complex circuits are being formed in recent years, there has been more demand for better heat radiating properties from the substrate.

One method that is known for improving the heat radiating properties is to improve the thermal conductivity of the constituent materials of the substrate and the like. For example, WO 2002-045470 discloses a method for obtaining aluminum nitride with high thermal conductivity by reducing the residual carbon in an aluminum nitride molded body before firing it.

Another method that is known for improving the heat radiating properties is to use a thermal via. The heat generated in chips and other heat generators is transferred outside the substrate through the thermal via. JP 2002-158318 discloses a technique for promoting heat radiation by arranging a highly thermally conductive material on the periphery of a thermal via.

A thermal via can be made larger in order to improve its heat radiating properties, but if it is too large there will be insufficient adhesion between the filler of the thermal via and the sides of the thermal via, and the filler may fall out if external pressure is applied.

It is desirable to provide a method for ensuring adhesion between the filler of a thermal via and the sides of the thermal via in a thermal via with a large opening.

### SUMMARY OF THE INVENTION

The present invention is a ceramic substrate having a thermal via passing through the substrate for purposes of radiating heat to the outside of the substrate, wherein the ceramic substrate has a reinforcing structure that divides the opening of the thermal via into two or more, and the height of the reinforcing structure is less than the height of the thermal via.

The present invention is also directed to a method for manufacturing this ceramic substrate and to an electronic component comprising this ceramic substrate.

By providing a reinforcing structure meeting specific conditions inside the hole of a thermal via on a ceramic substrate, it is possible to increase the joining strength between the ceramic substrate and the filler inside the thermal via, thereby dropout of the filler due to external pressure.

### BRIEF DESCRIPTION OF THE DRAWING(s)

FIGS. 1A and 1B show the structure of a ceramic substrate of one embodiment of the present invention, with FIG. 1A being a top view and FIG. 1B a cross-sectional view;

FIG. 2A and 2B is a drawing explaining the relationship between the thermal via and reinforcing structure in the ceramic substrate of the present invention, with FIG. 2A and 2B showing a top view and cross sectional view of one embodiment of the present invention and FIG. 2C through FIG. 2H showing views of comparative examples;

FIG. 3 is a drawing explaining the relationship between the thermal via and reinforcing structure in the ceramic substrate of the present invention, with FIG. 3A and 3B show and top view and cross section of one embodiment of the present invention and FIG. 3C through FIG. 3D show comparative examples;

FIG. 4 is a drawing explaining the relationship between the thermal via and reinforcing structure in the ceramic substrate of the present invention, with FIG. 4A and 4B show one embodiment of the present invention and FIG. 4C through FIG. 4H show comparative examples;

FIG. 5 is a drawing explaining the relationship between the thermal via and reinforcing structure in the ceramic substrate of the present invention, with FIG. 5A, 5B and C show one embodiment of the present invention and FIG. 5D through FIG. 5I showing comparative examples;

FIG. 6A-6D is a drawing explaining the ceramic substrate manufacturing method of the present invention;

FIG. 7A-7D is a drawing explaining a different method for manufacturing the ceramic substrate of the present invention;

FIG. 8A-8J is a drawing explaining the procedure for filling a via hole or the like in the ceramic substrate of the present invention with a filler composition;

FIG. 9 is a diagram showing one example of an electronic component of the present invention; and

FIG. 10 shows the shapes and the like of ceramic substrates prepared in the Examples of the present invention.

### DETAILED DESCRIPTION OF THE INVENTION

The present invention relates to the structure of a ceramic substrate having a thermal via that passes through the substrate for purposes of radiating heat to the outside. In particular, in the ceramic substrate of the present invention, the thermal via has a reinforcing structure that divides the opening of the via into two or more, and the height of this reinforcing structure is less than the height of the thermal via.

An alumina, aluminum nitride, zirconium oxide or known silica, glass or other substrate can be used for the ceramic substrate of the present invention.

The material of the reinforcing structure contained in the thermal via is not particularly limited as long as it can prevent dropout of the filler that fills the thermal via, but it is preferably of the same material as the ceramic substrate.

The reinforcing structure in the thermal via of the present invention can have any structure as long as it divides the opening of the thermal via into two or more, and as long as the height of the reinforcing structure is less than the height of the thermal via.

One embodiment of the ceramic substrate of the present invention, having a thermal via containing a reinforcing structure, has the structure shown in FIG. 1 for example. FIG. 1A shows a top view while FIG. 1B shows an a-a′ cross-section.

In this embodiment, as shown in FIG. 1A, ceramic substrate 100 has substrate body 102 and thermal via 104, and thermal via 104 is divided equally into four by reinforcing structure 106 (in these Specifications, reinforcing structure 106a (shown vertically) and reinforcing structure 106b (shown horizontally) are together called 106). As shown in the cross-section of FIG. 1B, reinforcing structure 106 is formed vertically from opening 110 at one end (bottom) of the thermal via towards opening 108 at the other end (top), and its height a is less than that of the thermal via (the height a of the reinforcing structure and height h of the thermal via are as defined below). In FIG. 1, the reinforcing structure and thermal via are each shown formed as rectangles perpendicular to the thickness of the ceramic substrate (a form which is preferred in the present invention), but the present invention is not limited to this structure, and for example the reinforcing structure and thermal via may have a trapezoidal cross-section in which the top opening 108 is larger than the bottom opening 110.

As used herein, the terms “top opening” and “bottom opening” indicate, respectively, the side for mounting a component from which heat is to be radiated (such as a LED chip), and the side for not mounting such a component when the ceramic substrate is used as an electronic component. A top view in these specifications is a view seen from the side with the top opening.

As shown in this embodiment, a thermal via having reinforcing structure 106 of the present invention is divided into two or more by the reinforcing structure. In the example above it is divided into 4, but for example the thermal via can be divided into only two by either the reinforcing structure 106a (shown vertically) or the reinforcing structure 106b (shown horizontally) in FIG. 1, or the reinforcing structure can be arranged so as to divide the thermal via into three or more. The position of the reinforcing structure in the thermal via is also not particularly limited. That is, in one embodiment of the present invention the through hole of thermal via 104 was divided uniformly as shown in FIG. 1, but the reinforcing structure does not have to be designed this way in the present invention. The position of the reinforcing structure in the thermal via in the vertical direction (thickness) of the ceramic substrate is also not particularly limited, and the position can be selected appropriately within a range that prevents dropout of the filler that fills the via hole. In the present invention, the reinforcing structure is preferably formed as a rectangle extending vertically from the bottom opening 110 of the thermal via towards the top opening 108 as shown in FIG. 1B.

As described above, the reinforcing structure is provided inside the thermal via in substrate body 102 of the present invention. In addition to the specifications above, it is desirable that this reinforcing body fulfill all of the following conditions (i) through (iii):

(i) Given height a of the reinforcing structure and height h of the thermal via, a/h is in the range of 0.1 to 0.8;

(ii) Given top area b of the reinforcing structure and opening area s of the thermal via, b/s is in the range of 0.10 to 0.80;

(iii) Given opening area s of the thermal via and side area t of the thermal via, t/s is 4.0 or less.

The parameters for specifications (i) through (iii) above are explained below with reference to the drawings.

(Specification (i))

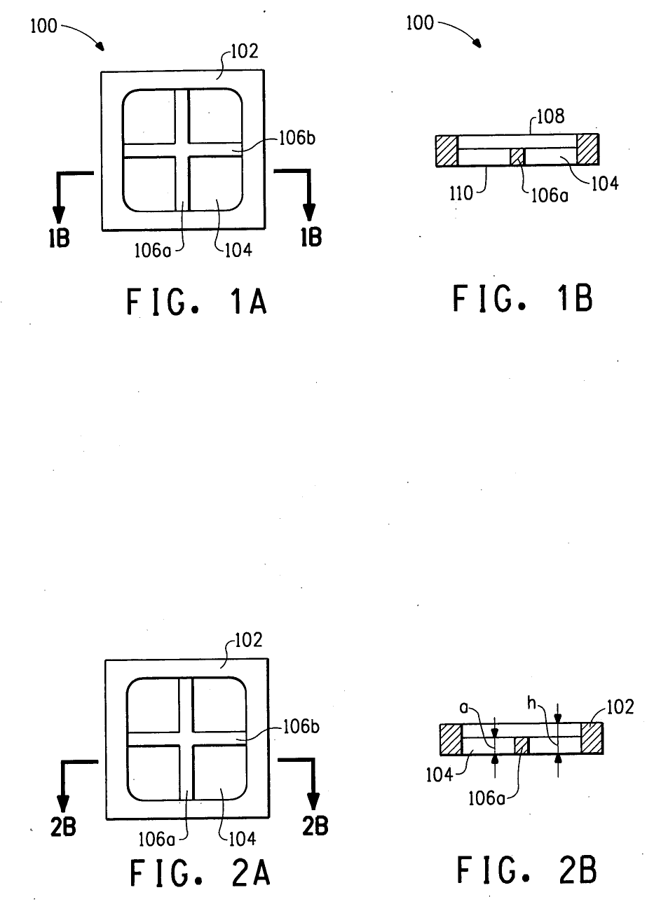

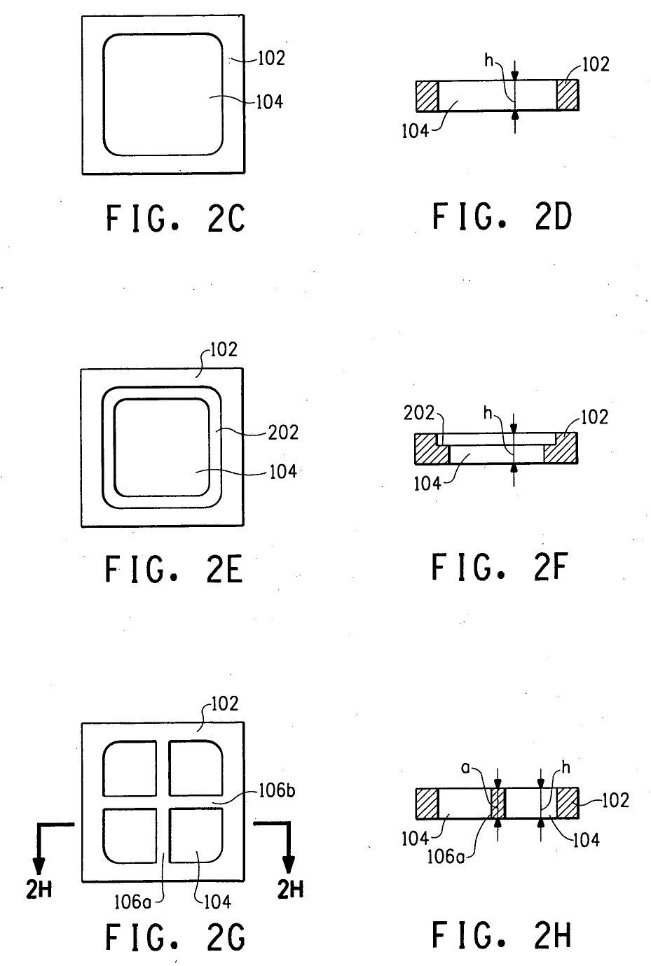

In specification (i), the “height a of the reinforcing structure” is the height of the reinforcing structure in the thermal via in the vertical direction (thickness direction) of the ceramic substrate. The “height h of the thermal via” in specification (i) is the height of the thermal via (through hole) in the ceramic substrate in the vertical direction (thickness direction). Specifically, the “height a of the reinforcing structure” and “height h of the thermal via” are explained with reference to FIG. 2A through FIG. 2H. FIG. 2 is only an example, however, and the present invention is not limited thereby. FIG. 2A and 2B show the same thermal via with reinforcing structure as in FIG. 1 above, which is desirable in the present invention, FIG. 2C and 2D show a thermal via without a reinforcing structure, FIG. 2E and 2F show an example with a step 202 (which is not a reinforcing structure) in the side of the thermal via, and FIG. 2G and 2H show an example with a reinforcing structure in which the reinforcing structure divides the thermal via into multiple holes and has the same height as the height h of the thermal via. In FIG. 2B, 2D, 2F and G, the cross-sections are the a-a′ cross section and d-d′ cross-section, respectively, in the top view.

As shown in FIG. 2A through FIG. 2G, the “height a of the reinforcing structure” signifies the height (shown as a) of reinforcing structure 106 in thermal via 104 in the direction of thickness (vertical direction) of the ceramic substrate. The “height h of the thermal via” signifies the height (shown as h) in the direction of thickness (vertical direction) of the ceramic substrate extending from one opening (top opening) 108 to the other opening (bottom opening) 110 regardless of whether there is a reinforcing structure 106.

(Specification (ii))

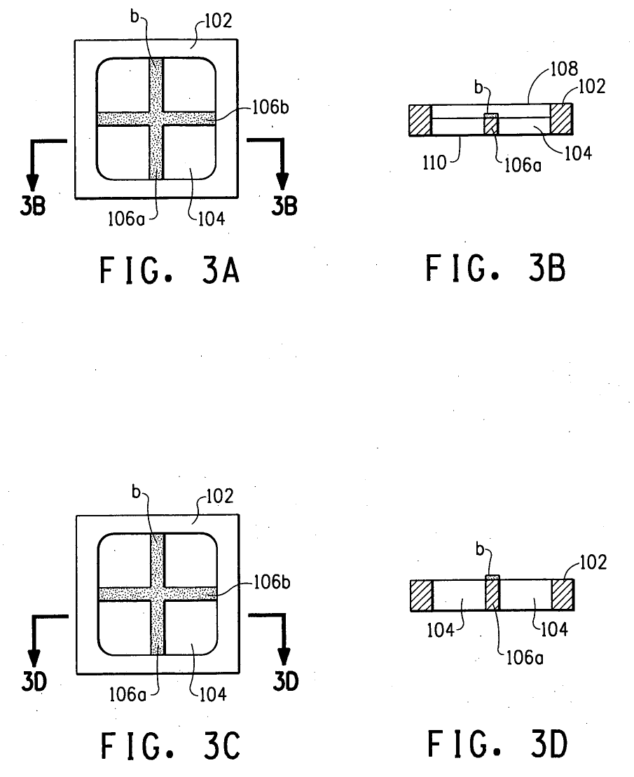

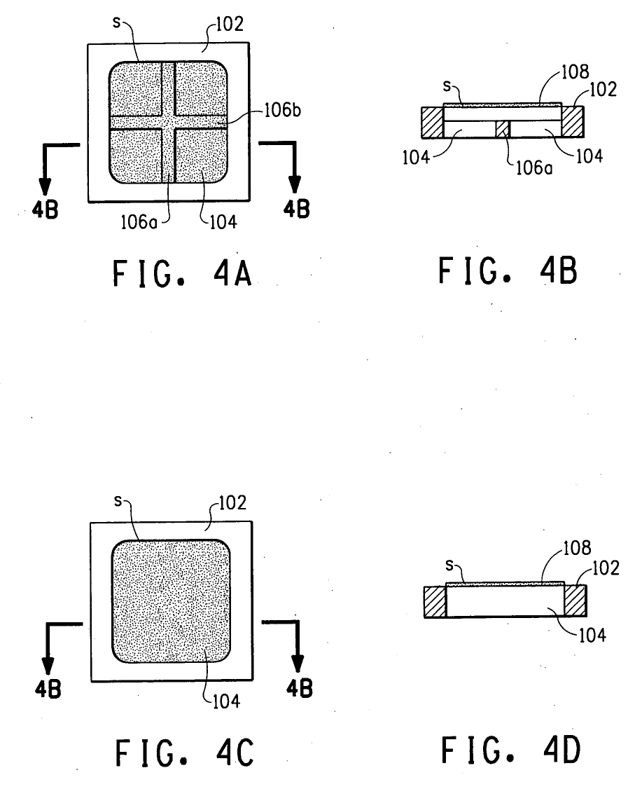

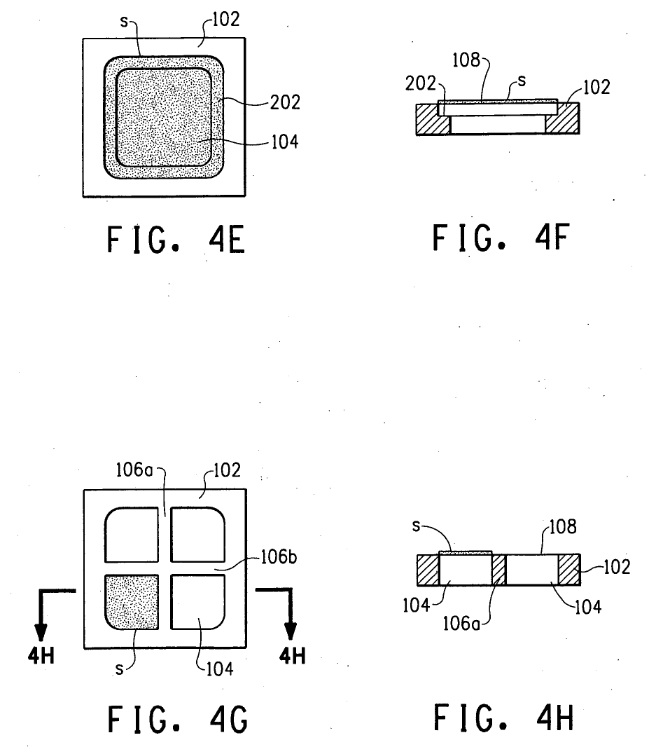

The “top area b of the reinforcing structure” in specification (ii) signifies the area of the top of the reinforcing structure facing the top opening in the thermal via. The “opening area s of the thermal via” in specification (ii) signifies the area of the top opening of the thermal via in the ceramic substrate. Specifically, the “top area b of the reinforcing structure” is explained with reference to FIG. 3A through FIG. 3D, while the “opening area s of the thermal via” is explained with reference to FIG. 4A through FIG. 4H. FIGS. 3 and 4 are only examples, however, and the present invention is not limited thereby. FIG. 3A and FIG. 4A show the same thermal via with reinforcing structure as in FIG. 1 above, which is desirable in the present invention, while FIG. 4C shows an example of a thermal via without a reinforcing structure and FIG. 4E shows an example with a step 202 (which is not a reinforcing structure) in the side of the thermal via, and FIG. 3C and FIG. 4G show examples with a reinforcing structure in which the reinforcing structure divides the thermal via into multiple holes and has the same height as the height h of the thermal via. In FIG. 3A and FIG. 3C, the cross-sections are the a-a′ cross-section and b-b′ cross-section, respectively, of the top view, while in FIG. 4A and FIG. 4G the cross-sections are the a-a′ cross-section and d-d′ cross-section, respectively, of the top view.

As shown in FIG. 3, the “top area b of the reinforcing structure” signifies the area of the top plane surface of reinforcing structure 106 in thermal via 104 that faces towards top opening 108 (the cross filled with dots in the top views of FIG. 3A and FIG. 3C and the part indicated by b throughout (same hereinafter) and the part shown by a heavy line in the cross-sections of FIG. 3A and FIG. 3C and the part indicated by b throughout (same hereinafter)). The “top area s of the thermal via” signifies the area of top opening 108 whether or not there is a reinforcing structure 106. More specifically, as shown in FIG. 4A, when the reinforcing structure has a height a that is less than the height h of the thermal via the area of the top opening is the area s of the top opening as a whole including the top area (part b in top view of FIG. 3A) of the reinforcing structure (the part filled with dots in the top view of FIG. 4A and the part indicated by s throughout (same hereinafter)), and the part shown with a solid line in the cross-section of FIG. 4A (part shown by s throughout, same hereinafter). As shown in FIG. 4C, when there is no reinforcing structure it is the area s of the top opening of the thermal via. As shown in FIG. 4E, when the thermal via is formed with a step at the edge of the thermal via hole it is the area s of the top opening as a whole including the step. Finally, as shown in FIG. 4G, when the reinforcing structure has the same height a as the height h of the thermal via, it is the area of the top opening of one of the holes that result from dividing the thermal via hole into two or more (part filled with dots in top view of FIG. 4G and indicated by s throughout (same hereinafter) and part shown by solid line in cross-section of FIG. 4H and also indicated by s in FIG. 4G (same hereinafter)).

(Specification (iii))

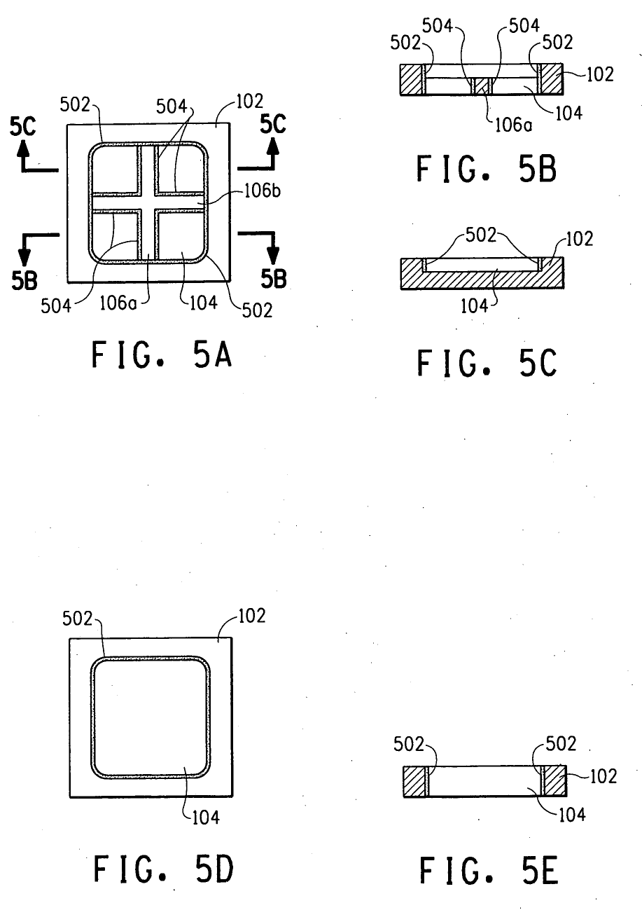

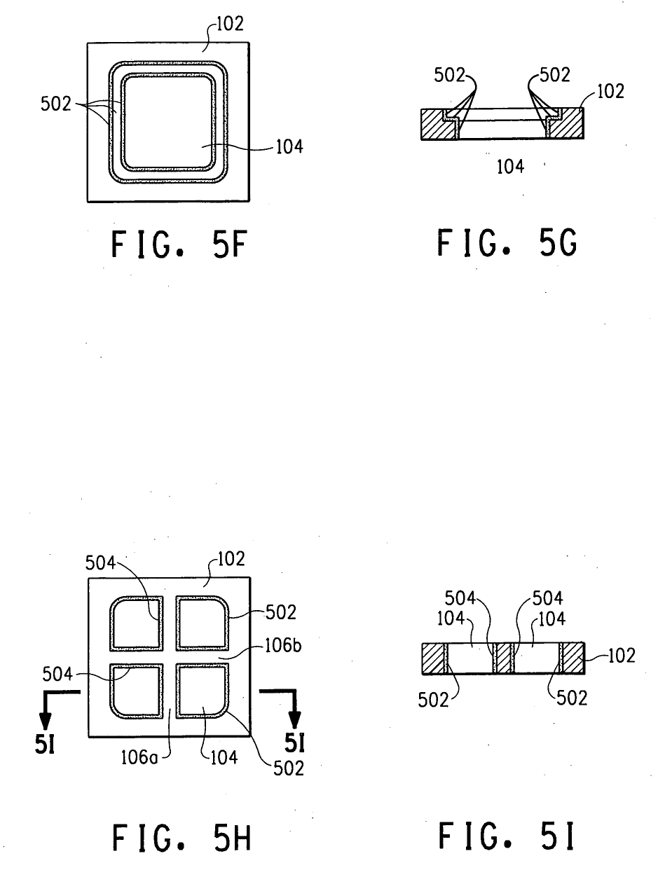

The “opening area s of the thermal via” in specification (iii) is as described under (ii) above. The “side area t of the thermal via” in specification (iii) is the area including the whole side face of the thermal via hole and the sides of the reinforcing structure if one is present. The “side area t of the thermal via” is explained in more detail with reference to FIG. 5A through FIG. 5E. However, FIG. 5 is only an example, and the present invention is not limited thereby. FIG. 5A shows an example of a thermal via with reinforcing structure which is desirable in the present invention as in FIG. 1, FIG. 5D shows an example of a thermal via without reinforcing structure, FIG. 5F shows an example having a step 202 (which is not a reinforcing structure) in the side of the thermal via, and FIG. 5H shows an example with a reinforcing structure in which the reinforcing structure divides the thermal via into multiple holes and has the same height as the height h of the thermal via. In FIG. 5A, cross-sections (5B) and (5C) are the a1-a1′ and a2-a2′ cross-sections, respectively, in the top view, while in FIG. 5H the cross-section is the d-d′ cross-section in the top view.

As shown in FIG. 5A, when the reinforcing structure has a height a that is less than the height h of the thermal via, the “side area t of the thermal via” is the area including the side 502 of the thermal via itself and the side area 504 of the reinforcing structure. When there is no reinforcing structure as in FIG. 5D, it is the area 502 of the thermal via in the vertical direction (direction of thickness). When the side of the thermal via hole has a step as in FIG. 5F, it is the side area t including the area 502 of the thermal via in the vertical direction (direction of thickness) and the area 502 of the step part. When the height a of the reinforcing structure is the same as the height h of the thermal via as shown in FIG. 5D, it is a combination of the area 502 of the entire side surface of the thermal via hole and the area 504 of the entire side surface of the reinforcing structure.

It should be pointed out that in order not to make the drawings too complex, the relevant symbols have not been indicated on all corresponding parts in FIGS. 1 through 5.

Next, the thermal via of the ceramic substrate of the present invention can be filled with a filler in order to increase thermal conductivity. This filler is composed of a filler composition containing a material with good thermal conductivity.

In the present invention, the filler composition includes a metal and a vehicle, and may optionally include thermally conductive materials other than metals.

The components of the filler composition are explained below.

### 1. Metal

The metal is not particularly limited but is preferably a material including one or two or more metals selected from the group consisting of silver, palladium, gold, platinum, copper, aluminum and nickel. These metals may be used in various forms including spheres, flakes and the like. The average particle size of the metal is not particularly limited but is preferably 0.5 to 8 μm or more preferably 1 to 6 μm.

### 2. Thermally Conductive Material

In addition to the aforementioned metal, the filler composition may include a thermally conductive material. The thermally conductive material other than metal is not particularly limited, but is preferably selected from the group consisting of silicon carbide (SiC), aluminum nitride (AlN), diamond and graphite.

### 2. Vehicle

The type of vehicle is not particularly limited. For example, an organic mixture of a binder resin (such as ethyl cellulose resin, acrylic resin, rosin modified resin, polyvinyl butyral resin or the like) and an organic solvent (such as butyl carbitol acetate (BCA), terpineol, ester alcohol, BC, TPO, etc.) can be used as the vehicle.

The content percentages of the metal, vehicle and thermally conductive material in the filler composition are 70 to 96 wt % or preferably 80 to 94 wt % of metal, 4 to 40 wt % or preferably 6 to 20 wt % of vehicle and 0 to 10 wt % or preferably 0.2 to 5 wt % of thermally conductive material based on the total weight of the composition.

The filler composition of the present invention may also contain glass powder or the like as an additional component. Glass powder is compounded to improve the adhesive force between the fired ceramic and the sintered composition. The content of glass powder is preferably 0.1 to 10 wt % or more preferably 0.2 to 5 wt % based on the total weight of the composition. The average particle size of the glass powder is preferably 0.1 μm to 5 μm or more preferably 0.3 μm to 3 μm.

The filler composition of the present invention can be suitably produced mixing the aforementioned components with a triple roll mill or the like.

The method for manufacturing the ceramic substrate of the present invention is explained next.

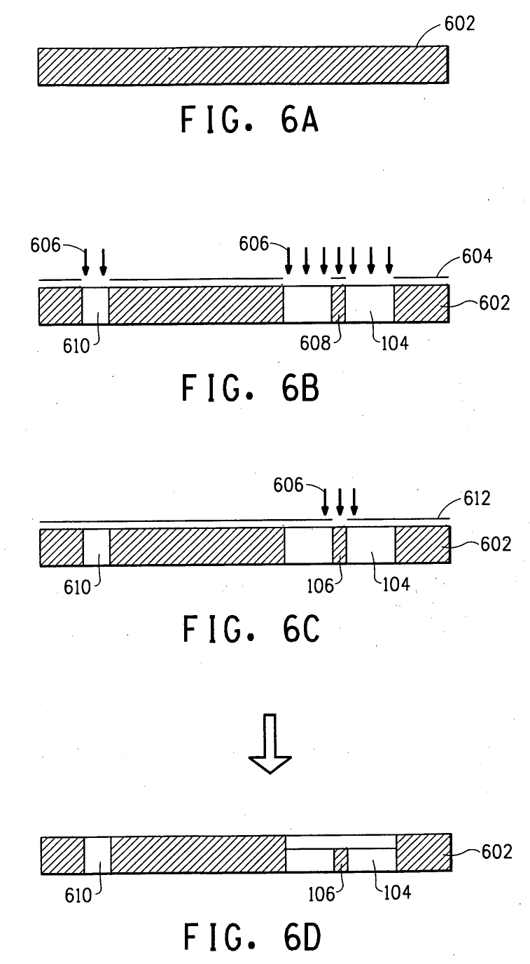

A ceramic substrate manufacturing method in which the via hole is formed by sandblasting or laser is explained as the first embodiment with reference to FIG. 6.

The ceramic substrate manufacturing method of the first embodiment is a method for manufacturing a ceramic substrate having a thermal via that passes through the substrate for purposes of radiating heat to the outside. Specifically, it includes (1) a step of providing the ceramic substrate and (2) a step of forming a thermal via having a reinforcing structure in the ceramic substrate by cutting with a sandblaster or laser, which is a step of forming a thermal via wherein the reinforcing structure thereof divides the opening of the thermal via into two or more, and the height of the reinforcing structure is less than the height of the thermal via.

Step 1 (see FIG. 6) of the manufacturing method of this embodiment is explained. In Step 1,6A ceramic substrate body 602 is prepared (this substrate is a commercial ceramic substrate such as a Tokuyama, Asahi Technoglass AlN substrate, Kyocera A1₂O₃ substrate or the like). The target ceramic substrate body can also be prepared as necessary by firing a green sheet consisting of a suitable material. Firing can be under suitable conditions and by suitable procedures according to the type of green sheet.

Next, in Step 2, 6Ba via hole having reinforcing structure 106 is formed in ceramic substrate body 602.

A sandblasting process, laser process, electron beam process or the like can be adopted for forming via-hole 104 with reinforcing structure 106 in ceramic substrate body 602. A through hole having reinforcing structure 106 is formed by these methods in the ceramic substrate body to make a thermal via. Specifically, in the sandblasting process fine sand 606 is blown through mask 604 having the shape of reinforcing structure 106 to thereby form a specific structure (reinforcing structure 608 for example as in the aforementioned FIG. 6B) by sandblasting. A ceramic substrate used for an electronic component will also have a small-diameter circuit via-hole for conduction purposes in addition to the thermal via. In the configuration of FIG. 6, the large-diameter via hole 104 constitutes a thermal via (including reinforcing structure 106) for radiating the heat of a mounted component, while the small-diameter via-hole 610 is a circuit via-hole.

Once the through hole is formed, in order to reduce the height of reinforcing structure 606 to less than the height of the via-hole, the sandblasting process can be applied through mask 612 (which lacks the shape of the reinforcing structure) until reinforcing structure 106 reaches the specified height. In the case of laser processing or electron beam processing, the laser or electron beam can be scanned to cut ceramic substrate body 602 until reinforcing structure 106 reaches the specified height. The conditions for laser or electron beam processing differ depending on the ceramic substrate body being cut. The conditions for exposing the ceramic substrate body can be selected appropriately from conventional technologies.

The size of the thermal via (through hole) is not particularly limited, but preferably the area of through hole on a plane parallel to the surface of the substrate is 4 mm² or more. More specifically, if the thermal via is circular it preferably has a relatively large diameter of 2.5 mm or more.

Next, a method for manufacturing a ceramic substrate using a green sheet is explained with reference to FIG. 7 as the 2^{nd} embodiment.

This method is a method for using a green sheet to manufacture a ceramic substrate having a thermal via passing through the substrate for radiating heat to the outside, wherein the thermal via also has a reinforcing structure. Specifically, it comprises (1),7A, a step of preparing (7a) a ceramic green sheet having a thermal via not formed with a reinforcing structure that divides the opening of the thermal via into two or more and (7b) a ceramic green sheet formed with a reinforcing structure that divides the opening of the thermal via into two or more, (2)7B, a step of laminating these ceramic green sheets together to form a laminated green sheet having a reinforcing structure that divides the opening of the thermal via into two or more and has a height less than the height of the thermal via, and (3)7C, a step of firing this laminated green sheet.

Step 1 is a step of preparing the green sheets of (a) and (b) above.

First, green sheets 702 and 704 without through holes (FIG. 7A) are prepared as the foundation for these green sheets.

In the case of a low-temperature fired ceramic for example, the green sheets may consist of a mixture of 50 to 65 wt % CaO—SiO₂—Al₂O₃—B₂O₃ glass and 50 to 35 wt % alumina. In addition, for example a mixture of MgO—SiO₂—Al₂O₃—B₂O₃ glass and alumina, a mixture of SiO₂—B₂O₃ glass and alumina, a mixture of PbO—SiO₂—B₂O₃ glass and alumina, or cordierite crystallized glass or another low-temperature fired ceramic material that is fired at 800 to 1000° C. can be used.

Next, through holes 706, 708 and 710 as the via holes are provided at specific positions on green sheet 702 corresponding to (a) and green sheet 704 corresponding to (b) (see FIG. 7B). Through holes 708 are formed in the green sheet corresponding to (b) leaving part 712 for the reinforcing structure. Through hole 706 forms the part of the opening without reinforcing structure 106 in thermal via 104, and through holes 708 form the part of the opening with reinforcing structure 106 in thermal via 104. Through hole 710 is a circuit via hole. All through holes can be formed by punching process.

One means of forming the through holes for the via holes is a method of forming through holes of a specific size by punching the green sheet as described above, but as explained in the first embodiment, other methods are to form the through holes by sandblasting or laser or electron beam processing.

In the present invention, multiple green sheets (a) and (b) can be prepared and laminated in order to obtain a green sheet of the desired thickness.

Next, Step 2 is explained. Step 2 is a step of laminating the green sheets of (a) and (b) to form a green sheet having a reinforcing structure (FIG. 7C).

First, after completion of Step 1, the resulting green sheets are laminated and pressed for bonding (FIG. 7C). When there are multiple green sheets (a) and green sheets (b), these green sheets are laminated to form a laminate having the desired reinforcing structure.

Specifically, the green sheets obtained by Step 1 are heated and pressed for bonding under conditions of for example 60 to 150° C., 0.1 to 30 MPa (preferably 1 to 10 MPa) to form a unit.

Step 3 is a step of firing the green sheet laminate obtained in Step 2 (FIG. 7D).

The laminate obtained in Step 2 is fired. Specifically, the green sheet laminate can be fired for example under conditions of 800 to 1000° C. (preferably 900° C.), maintained for 20 minutes.

As explained with respect to the manufacturing method of the first embodiment, a ceramic substrate used for an electronic component has a small-diameter circuit via hole e for conduction purposes in addition to the thermal via. In the configuration of FIG. 7, large-diameter via hole 104 is a through hole having reinforcing structure 106 and constituting a thermal via for radiating heat from a mounted component, while small-diameter via hole 610 is a circuit via hole.

In the ceramic substrate of the present invention, the via hole can be filled with a filler. More efficient heat diffusion as well as conduction for circuit can be achieved by means of this filler.

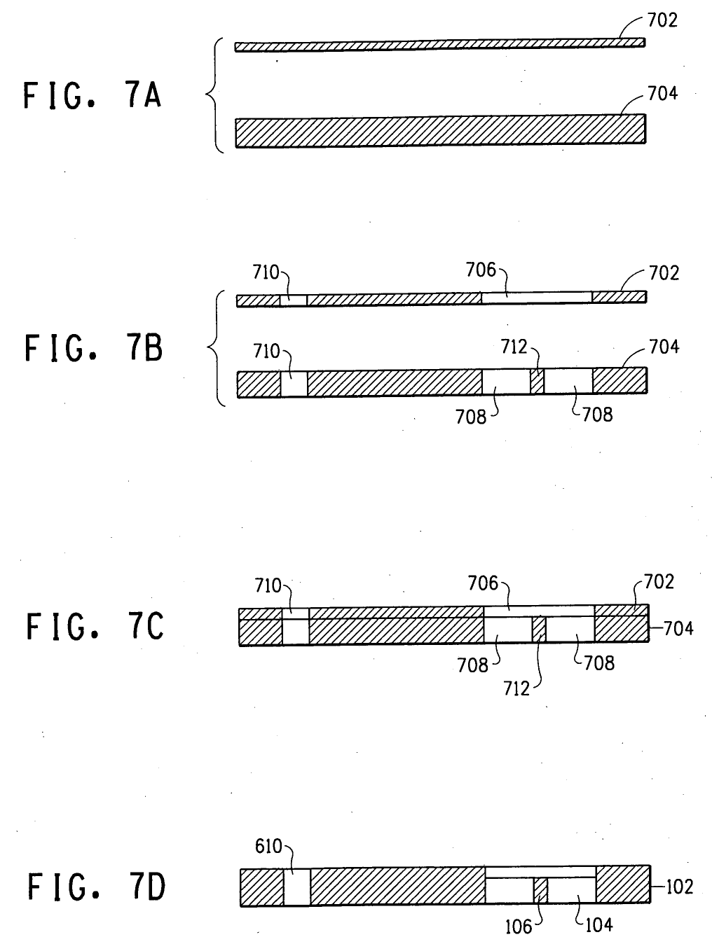

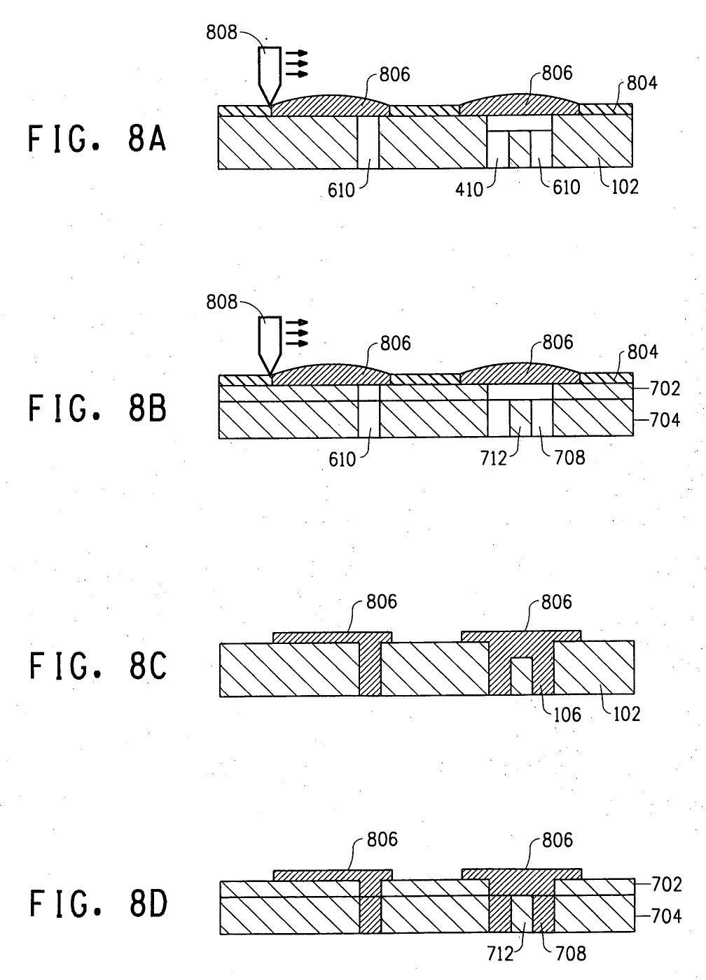

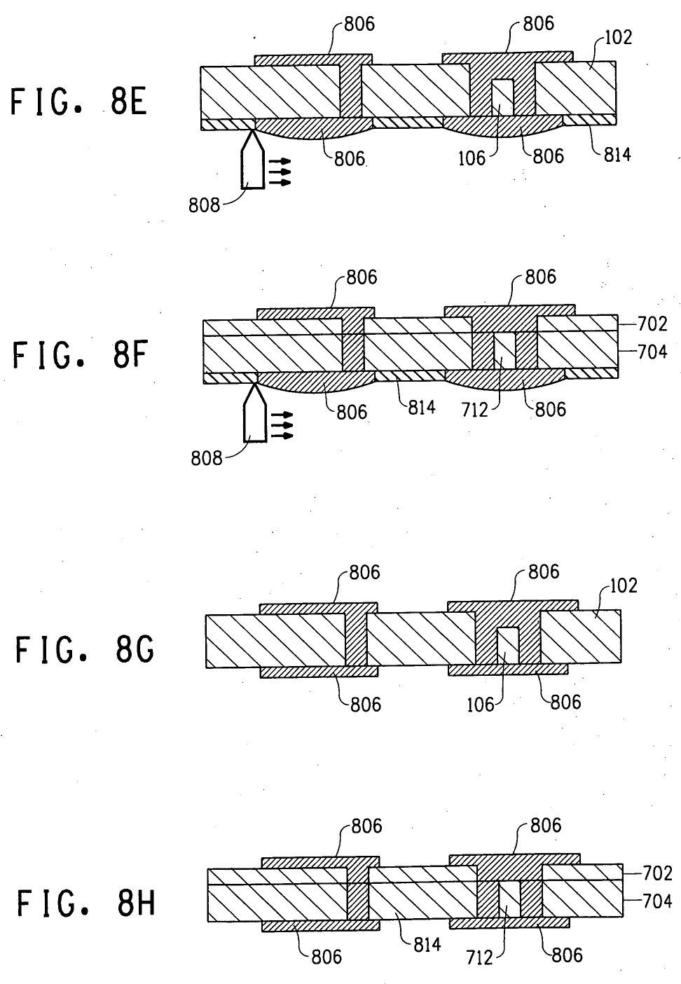

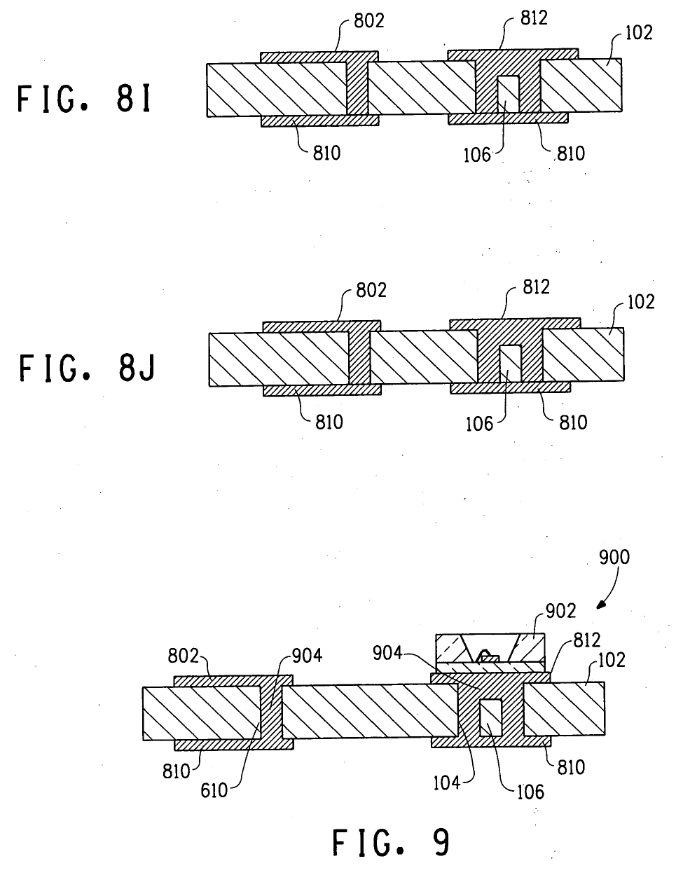

The procedures for filling with this filler are explained below with reference to FIG. 8. In the ceramic substrate manufacturing method of the present invention, the via hole can be filled with a filler composition after Step 2 in the 1^{st} embodiment and between Step 2 and Step 3 in the 2^{nd} embodiment. Specifically this is done as follows. FIG. 8A through FIG. 8H show the filling procedure of the 1^{st} embodiment, while FIG. 8A′ through FIG. 8H′ show the filling procedure of the 2^{nd} embodiment.

First, through holes 104 and 610 formed in ceramic substrate body 102 or through holes 104, 610 and 708 in a laminate of green sheets 702 and 703 are filled with a filler composition. The filler composition may be that explained above. Normally, filling is achieved by a printing process. In the 1^{st} embodiment through hole 104 contains reinforcing structure 106, while in the 2^{nd} embodiment through hole 708 contains part 712, which will be the reinforcing structure.

In order to reduce manufacturing costs, the through holes 104, 610 and 708 in ceramic substrate 102 or green sheets 702 and 704 can be filled at the same time that the wiring pattern is printed. In such a case, the aforementioned filler composition can also be used for the wiring pattern.

In the simultaneous printing step, screen mask 804 having formed thereon a printing pattern for filling through holes 104, 610 and 708 and for printing the part that will be wiring pattern 802 is set on ceramic substrate body 102 or green sheet 702, filler composition 806 is supplied above this screen mask, and squeegee 808 is slid along the top surface of this screen mask to simultaneously fill the through holes and print the wiring pattern (FIG. 8A and FIG. 8A′ through FIG. 8B and FIG. 8B′). It is also desirable to simultaneously form a conductor pattern other than the wiring pattern, corresponding to component mounting land 812 or the like, by printing on the upper surface of the opening of the part corresponding to thermal via 104. When using a green sheet, the parts corresponding to surface layer wiring pattern 802, component mounting land 812 and the like can also be printed after the green sheet is fired.

Following the aforementioned printing, the part that will be reverse wiring pattern 810 is printed on the lower surface of the via hole opening on ceramic substrate body 102 and green sheet 704 (FIG. 8E and FIG. 8F′ through FIG. 8G and FIG. 8H′). Screen mask 814 having formed thereon the printing pattern for printing the part corresponding to reverse wiring pattern 810 is set on the bottom of ceramic substrate body 102 or green sheet 704, filler composition 806 is supplied above the screen mask and squeegee 808 is slid along the upper surface of the screen mask.

By these steps, the filler composition of the present invention can be applied to the parts corresponding to surface layer wiring pattern 802, reverse wiring pattern 810 and mounting land 812, and filled into through holes 104, 610 and 708 (FIG. 8G and FIG. 8H′).

Next, the filler composition or the filler composition and green sheet are fired (FIG. 8I and FIG. 8J′). The conditions for drying and firing the filler composition in the present invention can be determined suitable for the substrate and the application by using official notice as necessary. For example, when using a ceramic or glass substrate as an electronic circuit substrate, the composition can be first filled and printed by a printing process, dried for 5 to 60 minutes at a temperature in the range of 70° C. to 200° C., and then fired in a belt oven, box oven or the like with a total firing time of 20 to 120 minutes and maintained for 5 to 30 minutes at a top temperature in the range of 450° C. to 900° C.

An electronic component of the present invention is explained below.

An example of an electronic component of the present invention is shown in FIG. 9. FIG. 9 is a vertical cross-section showing a model view of one example using a ceramic substrate of one embodiment of the present invention. The present invention is not limited to the embodiment shown in FIG. 9, however, and can be applied to various types of electronic components having via holes.

As shown in FIG. 9, this electronic component has substrate 102 with specific dimensions and via holes 104 and 610 at specific positions thereon. Resistors and various other circuit components (not shown) and wiring patterns 802, 810 and the like are formed on one or both surfaces of the substrate, and mounted component 902 (an LED chip or the like for example) is mounted on mounting land 812. Via hole 104 and via-hole 610 are filled with filler 904, which is formed of the filler composition described above. In the configuration of FIG. 9 the large-diameter via hole 104 is a thermal via for radiating the heat from mounted component 902, while the small-diameter via hole 610 is a circuit via hole.

In addition to the ceramic substrate manufacturing methods and filler composition filling procedures explained above, an electronic component such as that shown in FIG. 9 can be manufactured by using conventional methods to form various circuit components to obtain an electronic circuit substrate on which mounted components can then be mounted as necessary. In these Specifications, however, an electronic circuit substrate is a ceramic substrate having various circuits formed and the filler filled by the aforementioned procedures, but without any mounted components.

The electronic component and electronic circuit substrate of the present invention may comprise a single-layer substrate such as that described above, or may have multiple substrates of specific dimensions laminated together with various circuit components and via-holes at specific positions on each substrate. In the case of such a multilayer substrate, the conduction via holes do not have to be at the same position on each substrate, but may be formed at different positions. However, the thermal via is preferably formed at the same position on each substrate in order to efficiently transmit heat to the back of the substrate.

By using the ceramic substrate of the present invention it is possible to prevent dropout of the filler that fills the large-diameter thermal via in the electronic component, and to thereby maintain good electrical and thermal conductivity of the via hole.

An electronic component manufactured using the ceramic substrate of the present invention can be used for various applications. For example, it can be used for the high-frequency circuit of a mobile phone, the heat-sink circuit of an LED or the like.

### EXAMPLES

The present invention is explained in detail below using examples, but these examples are only examples and do not limit the present invention.

In these examples, the substrate material, filler materials, substrate, printing on the substrate, drying and firing and evaluation conditions are as follows.

### (1) Substrate

A 2-inch square, 0.635 mm thick AlN substrate (Asahi Technoglass substrate 230 W/m·K) was used.

### (2) Via Hole Formation

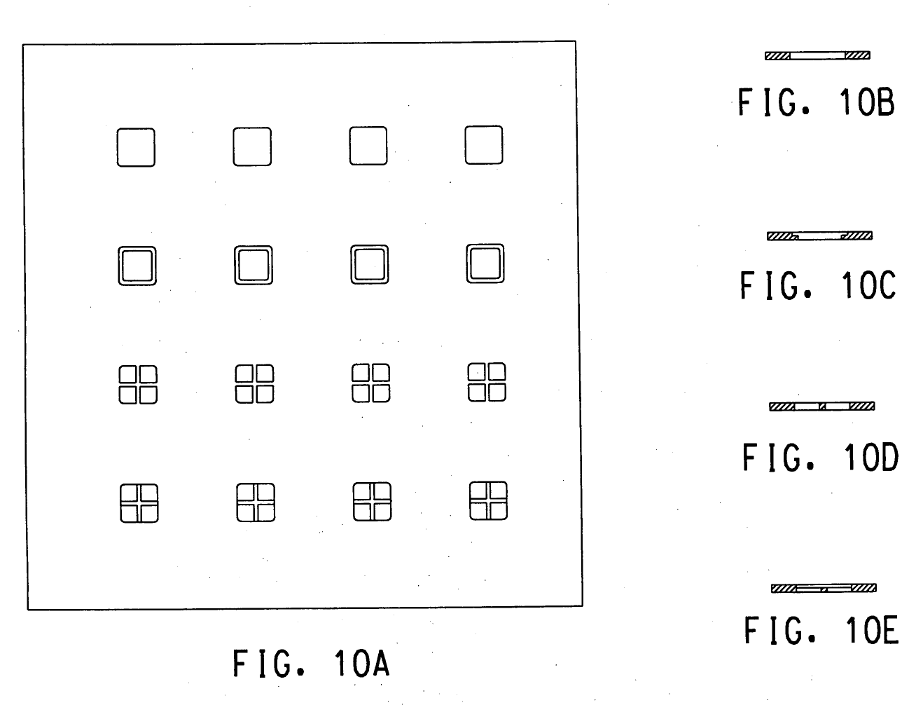

4 via-holes of the shapes and dimensions shown in FIG. 10 were formed by sandblasting on each AlN substrate.

### (3) Filling the Via-Holes

The filler composition was prepared by measuring 92 wt % of metal with a compositional ratio of silver: palladium=95:5 and 8 wt % of vehicle (cellulose vehicle), agitating them thoroughly in a mixer and then dispersing them with a triple roll mill. This filler composition was filled by printing in the via hole, dried, and fired to prepare the filler.

### (4) Printing, Drying, Firing

The aforementioned filler composition was filled into the via hole on the substrate, dried and fired under the following conditions.

Printing: Using a 150 μm-thick stainless steel metal mask, Newlong automatic printer, flat urethane squeegee (hardness 70)

Drying: 20 minutes at 100° C. in a box-type air oven

Firing: 10 minutes, peak temperature 550° C., belt oven

### (5) Substrate Evaluation Method

The resulting substrate with filled via holes was surface polished. The polishing process consisted of 4 steps: surface grinding to remove a thin layer of the substrate surface, lapping, polishing and ultrasound cleaning. Lapping is a polishing process using rough free polishing powder. Polishing is a polishing process using fine free polishing powder. Ultrasound cleaning is performed to remove residual fine particles from the surface. Following ultrasound cleaning, the number of places where filler was retained after surface polishing was counted.

TABLE 1

| | | | Reinforcing | Thermal via | |
|---|---|---|---|---|---|
| | | Reinforcing | structure top | side area/ | Filler |
| | Via hole | structure | area/thermal via | thermal via | retention (%) |
| | &reinforcing | ht/Thermal via | opening area | opening | after surface |
| | structure | ht (a/h %) | (b/s %) | area (t/s %) | polishing |
| Ex 1 | FIG. 1 | 53 | 14 | 174 | 100 |
| CE 1 | FIG. 2C | 0 | 0 | 89 | 0 |
| CE 2 | FIG. 2E | 0 | 0 | 124 | 25 |
| CE 3 | FIG. 2G | 0 | 0 | 195 | 50 |

As shown in the Table, the thermal via with reinforcing structure of the present invention had a much higher filler retention rate than the thermal vias outside the scope of the present invention.

What is claimed is:

1. A ceramic substrate having a thermal via passing through the substrate for purposes of radiating heat to the outside,
wherein the ceramic substrate has a reinforcing structure that divides the opening of the thermal via into two or more sections, and the height of the reinforcing structure is less than the height of the thermal via.

2. The ceramic substrate according to claim 1, wherein given “a” as the height of the reinforcing structure and “h” as the height of the thermal via, a/h is 0.1 to 0.8, and given “b” as the top area of the reinforcing structure and “s” as the opening area of the thermal via, b/s is 0.10 to 0.80, and given “s” as the opening area of the thermal via and “t” as the side area of the thermal via, t/s is 4.0 or less.

3. The ceramic substrate according to claim 1, wherein the ceramic substrate is formed from an inorganic compound selected from the group consisting of alumina, aluminum nitride, zirconia oxide and glass.

4. The ceramic substrate according to claim 1, wherein the thermal via is filled with a material comprising one or two or more metals selected from the group consisting of silver, palladium, gold, platinum, copper, aluminum and nickel.

5. The ceramic substrate according to claim 4, wherein the thermal via is also filled with a material which has good thermal conductivity and is selected from the group consisting of silicon carbide (SiC), aluminum nitride (AlN), diamond and graphite.

6. A method for manufacturing a ceramic substrate having a thermal via passing through the substrate for purposes of radiating heat to the outside, the method comprising:
(1) a step of providing a ceramic substrate; and
(2) a step of forming a thermal via having a reinforcing structure in the ceramic substrate by sandblasting or laser or electron beam cutting, wherein the reinforcing structure divides the opening of the thermal via into two or more, and the height of the reinforcing structure is less than the height of the thermal via.

7. A method for manufacturing a ceramic substrate having a thermal via passing through the substrate for purposes of radiating heat to the outside, the thermal via having a reinforcing structure, the method comprising:
(1) a step of preparing (a) a ceramic green sheet having a thermal via not formed with a reinforcing structure that divides the opening of the thermal via into two or more and (b) a ceramic green sheet formed with a reinforcing structure that divides the opening of the thermal via into two or more;
(2) a step of laminating the ceramic green sheets together to thereby form a laminated green sheet having a reinforcing structure that divides the opening of the thermal via into two or more and has a height less than that of the thermal via; and
(3) a step of firing the laminated green sheet.

8. An electronic component comprising the ceramic substrate of claim 1.
